(19) United States
(12) Patent Application Publication
(10) Pub. No.: US 2011/0068832 A1
(43) Pub. Date: Mar. 24, 2011

(54) DRIVING CIRCUIT FOR POWER MOSFET

(76) Inventors: Ying-Pei Chen, Taoyuan County (TW); Ming-Wei Huang, Taoyuan County (TW)

(21) Appl. No.: 12/608,008

(22) Filed: Oct. 29, 2009

(30) Foreign Application Priority Data
Sep. 22, 2009 (TW) 098131902

(51) Int. Cl. H03B 1/00

(52) U.S. Cl. 327/109

(57) ABSTRACT

A driving circuit for a power MOSFET includes a first switch, a second switch, a third switch and a fourth switch. The first switch is connected to a first node, a second node and a first power end. The first power end supplies a first voltage. The second switch is connected to the first node, the second node and a first ground end. The third switch is connected to the second node, a third node and the first power end. The fourth switch is connected to the second node, the third node and a second ground end. The power MOSFET is connected to the third node and a PWM signal is inputted into the first node. The PWM signal has a second voltage lower than the first voltage.

### BACKGROUND OF THE INVENTION

1. Field of the Invention

The invention relates to a driving circuit for a power metal-oxide-semiconductor field-effect transistor (MOSFET) and, more particularly, to a driving circuit capable of reducing conduction loss and switching loss of a power MOSFET.

2. Description of the Prior Art

Referring to FIG. 1, FIG. 1 is a schematic diagram illustrating a boost circuit 1 of the prior art. The boost circuit 1 comprises an inductor 10 a Schottky diode 12, a loading 14 a pulse width modulation (PWM) signal generating unit 16 and a power MOSFET 18. It should be noted that the connecting relation between the aforesaid components is shown in FIG. 1 and the principle thereof can be achieved by one skilled in the art, so it will not be depicted here again.

As shown in FIG. 1, when the loading 14 is overload, the power MOSFET 18 should be able to be adapted to high power, so as to supply high voltage for driving the overload. However, since the power MOSFET 18 can endure high voltage, a drain-source on-state resistance (Rds(on)) and a parasitic capacitance of the power MOSFET 18 will be large, so that conduction loss and switching loss will get large during power conversion. Consequently, the efficiency of power conversion will get worse while the power loss increase.

Furthermore, U.S. Pat. No. 7,459,945 (hereinafter '945 patent) discloses a gate driving circuit disposed between a power MOSFET and a PWM signal and used for improving driving capability of the power MOSFET and reducing loss. The gate driving circuit of '945 patent comprises a switching control circuit, four switches, four Schottky diodes and an inductor. '945 patent utilizes the switching control circuit to control the four switches so as to charge/discharge the inductor. In other words, the switching control circuit, which is used for timing control, and the inductor, which is used for storing power, are necessary for '945 patent to improve the efficiency of power conversion of the power MOSFET. However, the switching control circuit and the inductor will increase circuit size and the inductor will cause electromagnetic interference (EMI) while being charged or discharged.

### SUMMARY OF THE INVENTION

Therefore, one objective of the invention is to provide a driving circuit for a power MOSFET. The driving circuit is disposed between a PWM signal generating unit and the power MOSFET. The driving circuit is capable of reducing conduction loss and switching loss of the power MOSFET, so as to solve the aforesaid problems.

According to one embodiment, the driving circuit of the invention comprises a first switch, a second switch, a third switch and a fourth switch. The first switch is connected to a first node, a second node and a first power end, and the first power end supplies a first voltage. The second switch is connected to the first node, the second node and a first ground end. The third switch is connected to the second node, a third node and the first power end. The fourth switch is connected to the second node, the third node and a second ground end.

In this embodiment, a power MOSFET is connected to the third node and a PWM signal is inputted into the first node. The PWM signal has a second voltage lower than the first voltage. When the PWM signal is high, the first and fourth switches are turned off and the second and third switches are turned on, so that the first voltage is outputted to the third node through the third switch, so as to turn on the power MOSFET. On the other hand, when the PWM signal is low, the first and fourth switches are turned on and the second and third switches are turned off, so that the power MOSFET discharges through the fourth switch and the second ground end.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a boost circuit of the prior art.

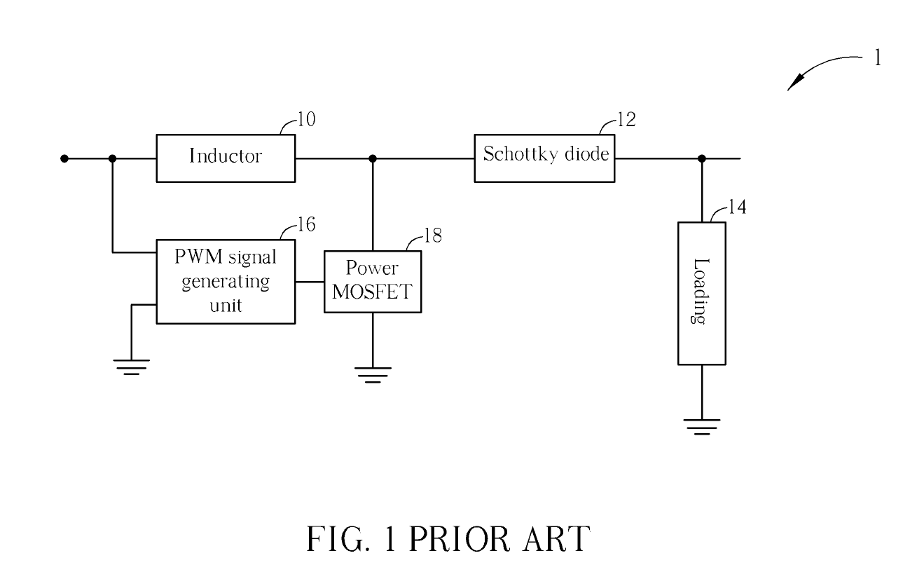

FIG. 2 is a schematic diagram illustrating a driving circuit according to one embodiment of the invention.

FIG. 3 is a timing diagram illustrating waveforms of each signal within the driving circuit.

FIG. 4 is a simulation waveform diagram illustrating the pulse signal at the gate of the power MOSFET.

FIG. 5 is a schematic diagram illustrating the driving circuit of the invention applied to a boost circuit.

FIG. 6 is a schematic diagram illustrating the driving circuit of the invention applied to an LED backlight driving circuit.

### DETAILED DESCRIPTION

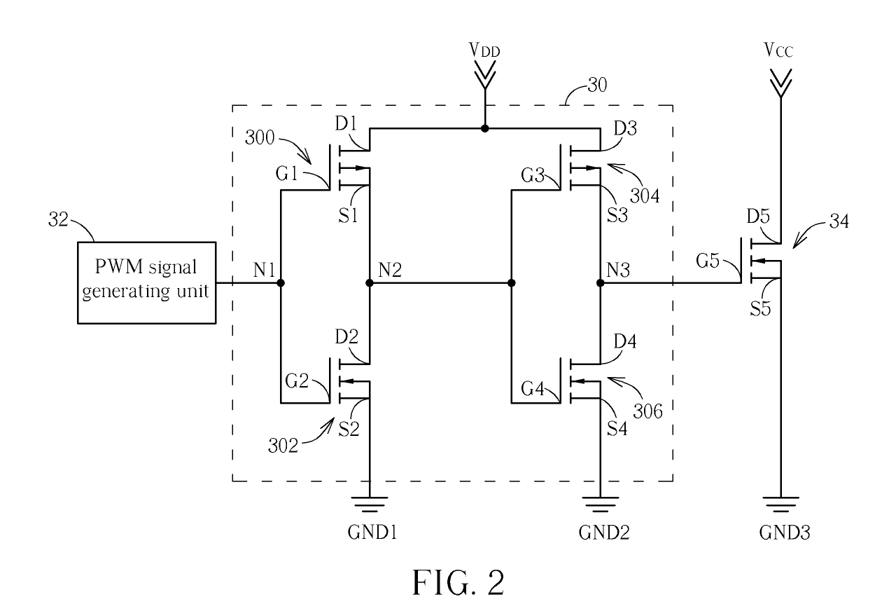

Referring to FIG. 2, FIG. 2 is a schematic diagram illustrating a driving circuit 30 according to one embodiment of the invention. As shown in FIG. 2, the driving circuit 30 is connected between a PWM signal generating unit 32 and a power MOSFET 34. The driving circuit 30 comprises a first switch 300, a second switch 302, a third switch 304 and a fourth switch 306. In this embodiment, the first and third switches 300 and 304 can be P-type transistors and the second and fourth switches 302 and 306 can be N-type transistors. In other words, an inverter consists of the first and second switches 300 and 302 and another inverter consists of the third and fourth switches 304 and 306.

The first switch 300 has a gate G1 connected to a first node N1, a source S1 connected to a second node N2, and a drain D1 connected to a first power end VDD. The second switch 302 has a gate G2 connected to the first node N1, a drain D2 connected to the second node N2, and a S2 source connected to a first ground end GND1. The third switch 304 has a gate G3 connected to the second node N2, a source S3 connected to a third node N3, and a drain D3 connected to the first power end VDD. The fourth switch 306 has a gate G4 connected to the second node N2, a drain D4 connected to the third node N3, and a source S4 connected to a second ground end GND2.

In this embodiment, the power MOSFET 34 is also an N-type transistor. The power MOSFET 34 has a gate G5 connected to the third node N3, a drain D5 connected to a second power end VCC, and a source S5 connected to a third ground end GND3. Furthermore, the PWM signal generating unit 32 is connected to the first node N1, so a PWM signal generated by the PWM signal generating unit 32 can be inputted from the first node N1 to the driving circuit 30.

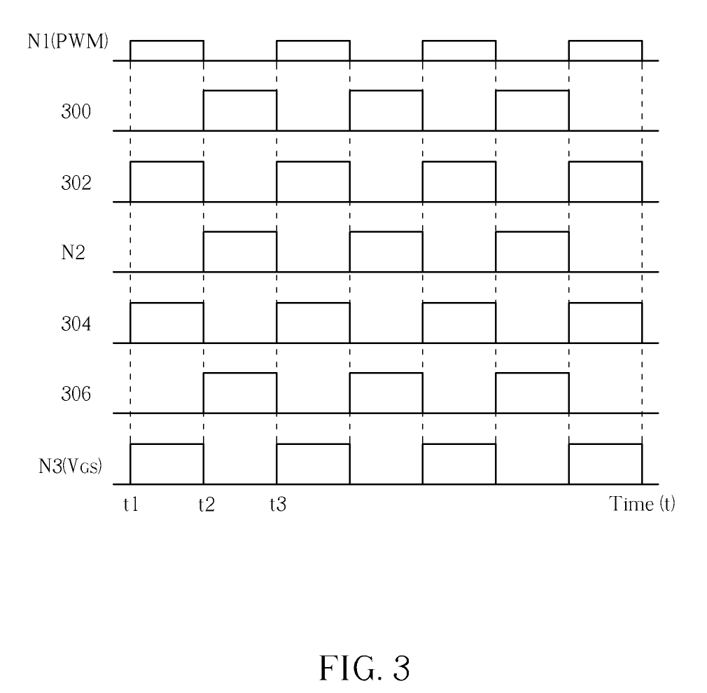

Referring to FIG. 3, FIG. 3 is a timing diagram illustrating waveforms of each signal within the driving circuit 30. At time t1 to t2, the PWM signal is high at the first node N1, so the first switch 300 is turned off and the second switch 302 is turned on, so that the PWM signal is converted from high to low at the second node N2. Since the second node N2 is low, the third switch 304 is turned on and the fourth switch 306 is turned off, so that the PWM signal is converted from low to high at the third node N3. At this time, the first voltage supplied by the first power end VDD will be outputted to turn on the power MOSFET 34 through the third switch 304 and the third node N3.

In this embodiment, the first voltage (e.g. 5V) supplied by the first power end VDD is larger than a second voltage (e.g. 3.3V) of the PWM signal. Accordingly, the driving circuit 30 of the invention can amplify the pulse of the PWM signal so as to amplify a gate-to-source voltage (V_{GS}) of the power MOSFET 34. Therefore, the number of charge carriers of the power MOSFET 34 will increase (i.e. the number of channel counts will increase), so as to increase conductance or reduce resistance. Consequently, the conduction loss is reduced and the efficiency of power conversion is enhanced. It should be noted that the first voltage has to be larger than the second voltage but the first and second voltages are not limited to the aforesaid 5V and 3.3V. The first and second voltages can be determined based on practical applications.

At time t2 to t3, the PWM signal is low at the first node N1, so the first switch 300 is turned on and the second switch 302 is turned off, so that the PWM signal is converted from low to high at the second node N2. Since the second node N2 is high, the third switch 304 is turned off and the fourth switch 306 is turned on, so that the PWM signal is converted from high to low at the third node N3. At this time, the power MOSFET 34 can discharge through the fourth switch 306 and the second ground end GND2.

The principle of the invention is depicted in detail in the above when the PWM signal is high or low during one operating cycle and the follow-up procedure can be obtained by the same manner. Therefore, it will not be depicted here again.

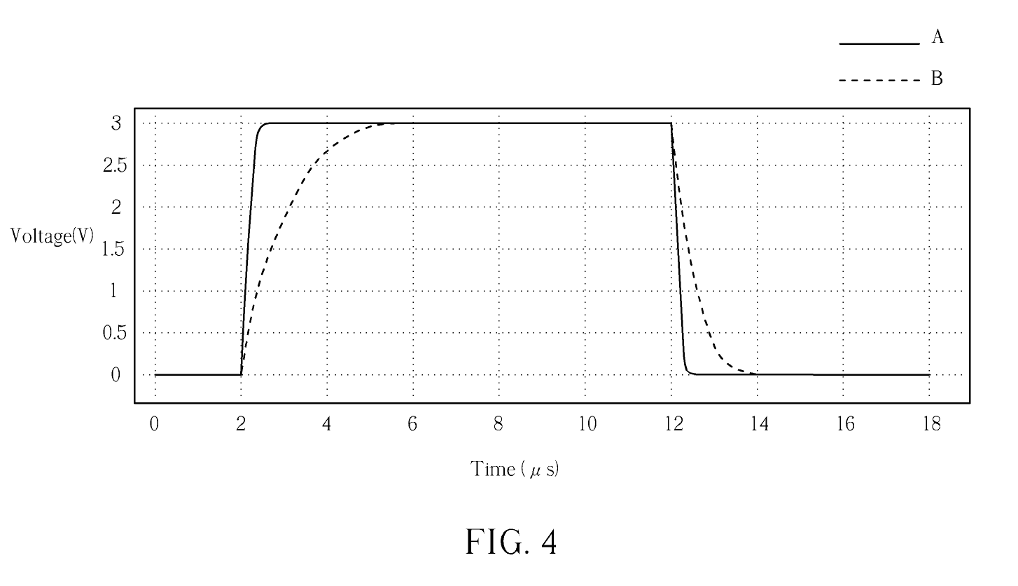

Referring to FIG. 4, FIG. 4 is a simulation waveform diagram illustrating the pulse signal at the gate G5 of the power MOSFET 34. As shown in FIG. 4, the real line A represents a simulation waveform after using the driving circuit 30 of the invention, and the broken line B represents another simulation waveform before using the driving circuit 30 of the invention. It is obvious that the driving circuit 30 of the invention can reduce charging/discharging time of the parasitic capacitance within the power MOSFET 34, wherein the power MOSFET 34 discharges through the fourth switch 306 and the second ground end GND2. Therefore, the switching loss can be reduced and then a square waveform of the pulse signal will be obtained at the gate G5 of the power MOSFET 34, as the real line A shown in FIG. 4.

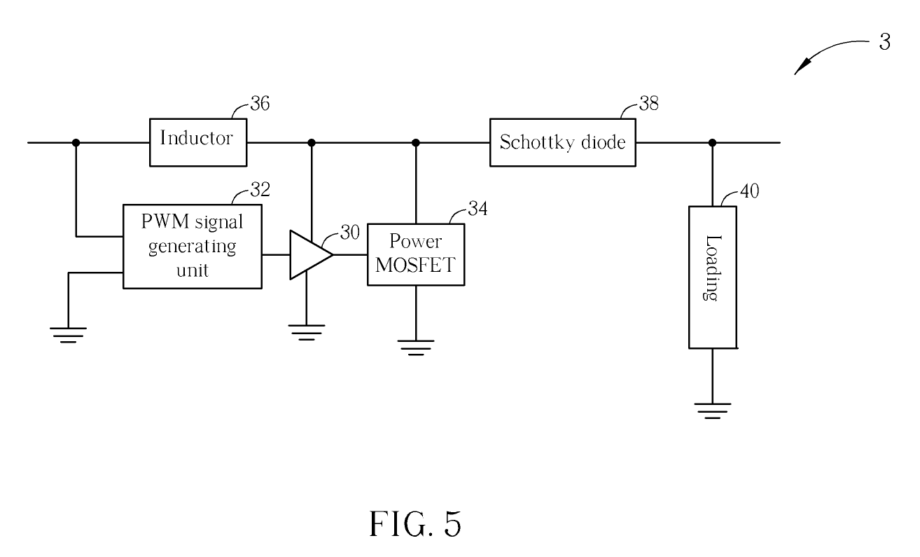

Referring to FIG. 5, FIG. 5 is a schematic diagram illustrating the driving circuit 30 of the invention applied to a boost circuit 3. The boost circuit 3 comprises the driving circuit 30, the PWM signal generating unit 32, the power MOSFET 34, an inductor 36 a Shottky diode 38 and a loading 40, wherein the loading is overload. As shown in FIG. 5, the driving circuit 30 is connected between the PWM signal generating unit 32 and the power MOSFET 34. The principle of the driving circuit 30 is mentioned in the above and will not be depicted here again. Furthermore, the connecting relation between the aforesaid components is shown in FIG. 5 and the principle thereof can be achieved by one skilled in the art, so it will not be depicted here again.

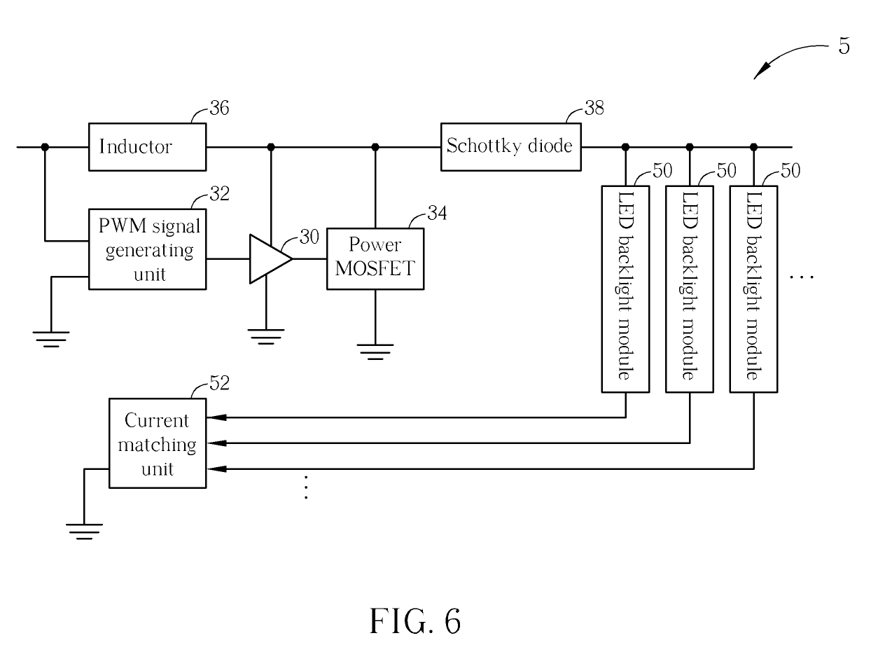

Referring to FIG. 6, FIG. 6 is a schematic diagram illustrating the driving circuit 30 of the invention applied to an LED backlight driving circuit 5. The LED backlight driving circuit 5 comprises the driving circuit 30, the PWM signal generating unit 32, the power MOSFET 34, the inductor 36, the Schottky diode 38, a plurality of LED backlight modules 50 and a current matching unit 52, wherein the LED backlight modules 50 are connected with each other in series and in parallel and equivalent to the loading 40 shown in FIG. 5. As shown in FIG. 6, the driving circuit 30 is connected between the PWM signal generating unit 32 and the power MOSFET 34. The principle of the driving circuit 30 is mentioned in the above and will not be depicted here again. Furthermore, the connecting relation between the aforesaid components is shown in FIG. 6 and the principle thereof can be achieved by one skilled in the art, so it will not be depicted here again.

Though the driving circuit 30 shown in FIG. 2 utilizes two inverters to reduce the conduction loss and switching loss of the power MOSFET 34, the invention is not limited to two inverters. If the frequency of the PWM signal gets high or the aforesaid first, second, third and/or fourth switch(es) 300-306 are/is not ideal, the invention can install more than two inverters (e.g. four, six and so on) in the driving circuit 30, so as to reduce the conduction loss and switching loss of the power MOSFET 34 more effectively and then obtain a square waveform at the gate G5 of the power MOSFET 34.

Compared to the prior art, the driving circuit of the invention consists of four switches and utilizes the PWM signal to control the four switches immediately, so as to reduce the conduction loss and switching loss of the power MOSFET effectively. The structure of the driving circuit of the invention is simple and the circuit size will not increase too much.

Those skilled in the art will readily observe that numerous modifications and alterations of the device and method may be made while retaining the teachings of the invention.

What is claimed is:

1. A driving circuit for a power metal-oxide-semiconductor field-effect transistor (MOSFET) comprising:
a first switch connected to a first node, a second node and a first power end, the first power end supplying a first voltage;
a second switch connected to the first node, the second node and a first ground end;
a third switch connected to the second node, a third node and the first power end; and
a fourth switch connected to the second node, the third node and a second ground end;
wherein the power MOSFET is connected to the third node, a pulse width modulation signal is inputted into the first node, and the pulse width modulation signal has a second voltage lower than the first voltage;
wherein when the pulse width modulation signal is high, the first and fourth switches are turned off and the second and third switches are turned on, so that the first voltage is outputted to the third node through the third switch, so as to turn on the power MOSFET;
when the pulse width modulation signal is low, the first and fourth switches are turned on and the second and third switches are turned off, so that the power MOSFET discharges through the fourth switch and the second ground end.

2. The driving circuit of claim 1, wherein the first switch is a P-type transistor having a gate connected to the first node, a source connected to the second node, and a drain connected to the first power end.

3. The driving circuit of claim 1, wherein the second switch is an N-type transistor having a gate connected to the first node, a drain connected to the second node, and a source connected to the first ground end.

4. The driving circuit of claim 1, wherein the third switch is a P-type transistor having a gate connected to the second node, a source connected to the third node, and a drain connected to the first power end.

5. The driving circuit of claim 1, wherein the fourth switch is an N-type transistor having a gate connected to the second node, a drain connected to the third node, and a source connected to the second ground end.

6. The driving circuit of claim 1, wherein the power MOSFET has a gate connected to the third node, a drain connected to a second power end, and a source connected to a third ground end.

7. The driving circuit of claim 1, wherein when the pulse width modulation signal is high, the first switch is turned off and the second switch is turned on, so that the pulse width modulation signal is converted from high to low at the second node.

8. The driving circuit of claim 7, wherein when the second node is low, the fourth switch is turned off and the third switch is turned on, so that the pulse width modulation signal is converted from low to high at the third node.

9. The driving circuit of claim 1, wherein when the pulse width modulation signal is low, the first switch is turned on and the second switch is turned off, so that the pulse width modulation signal is converted from low to high at the second node.

10. The driving circuit of claim 9, wherein when the second node is high, the fourth switch is turned on and the third switch is turned off, so that the pulse width modulation signal is converted from high to low at the third node.
